(19) United States
(12) Patent Application Publication
(10) Pub. No.: US 2014/0093722 A1
(43) Pub. Date: Apr. 3, 2014

(54) ELECTROMAGNETIC INTERFERENCE SHIELDING STRUCTURE

(71) Applicant: ITEQ CORPORATION, Taoyuan County (TW)

(72) Inventor: Yun-Hsing SUNG, Taoyuan County (TW)

(73) Assignee: ITEQ CORPORATION, Taoyuan County (TW)

(21) Appl. No.: 13/837,646

(22) Filed: Mar. 15, 2013

(30) Foreign Application Priority Data
Oct. 3, 2012 (TW) 101219136

(51) Int. Cl. H05K 9/00

(52) U.S. Cl. CPC H05K 9/0088
USPC 428/336

(57) ABSTRACT

The electromagnetic interference shielding structure disclosed comprises a first metal layer, a second metal layer, a dielectric layer inter-disposed between the first metal layer and the second metal layer, an adhesive layer located on the second metal layer, and a release film located on the adhesive layer. The electromagnetic interference shielding film prevent the neighbouring circuits and components from the electromagnetic wave interference, the theories applied are reflections of the electromagnetic waves, and absorption of the electromagnetic waves.

### FIELD OF THE INVENTION

The present invention relates to a structure against electromagnetic interference used for electronic devices, wirings and components, such as an electromagnetic interference shielding structure of a printed circuit board, in particular relates to a structure against electromagnetic interference of flexible electronic substrate.

### DESCRIPTION OF RELATED ART

Currently, the technologies of electronic industries are dedicated to develop electronic devices which are lighter, thinner and smaller. Printed circuit boards are required materials in electronic devices, and are becoming thinner, more compact and are high voltages resistance. Accordingly, the electromagnetic interference has become a major issue as electronic devices become lighter, thinner and smaller.

Generally speaking, an electromagnetic interference shielding structure comprises a dielectric layer and a metal layer. As shown in FIG. 2, an electromagnetic interference shielding structure 200 comprises a metal layer 202 using materials such as silver, copper and nickel, a second dielectric layer 204 above the metal layer 202 using materials such as soft epoxy resin, a first dielectric layer 206 above the second dielectric layer 204 using materials such as high wear resistant acrylic resin, a coverlay 208 above the first dielectric layer 206, and a conductive adhesive layer 210 used as a junction point of ground loop for the flexible printed circuit board (FPC), and a release film 212 for protecting the conductive adhesive layer form contaminating by external environment. Though the above electromagnetic interference shielding structure having outstanding flexibility, it is required to add grounding copper foils attached to the conductive adhesive layer at a source of the electromagnetic wave in the stack structure of the above-described materials. Accordingly, extra costs are generated from adding coverlays, and adding conductive glues for electromagnetic interference shielding structures.

### SUMMARY OF THE INVENTION

The objective of the present invention is to provide an electromagnetic interference shielding structure for reducing the cost of electromagnetic interference shielding structures, reducing the thickness of electromagnetic interference shielding structures and simplify the manufacturing procedures in FPC production.

In order to achieve the above objectives of the present invention, an electromagnetic interference shielding structure is provided comprising: a first metal layer, a second metal layer, a dielectric layer inter-disposed between the first metal layer and the second metal layer, an adhesive layer located on second metal layer, and a release film located on adhesive layer.

The advantages provided by an electromagnetic interference shielding structure of the presen

[symbol]

1. Reducing the cost of electromagnetic interference shielding structures: providing lateral chemical deposition stacking on the dielectric layer, growing a metal film on lateral sides of dielectric layers by vapor deposition or other methods, with thickness ranging from 6 (nm), which greatly reduces the overall cost.

2. Reducing the thickness of electromagnetic interference shielding structures: the thickness of a metal layer is reduced and the thickness of a dielectric layer is reduced by 1 micron, and the thickness used by a coverlay on a FPC is reduced.

3. Reducing FPC manufacturing procedures: an electromagnetic interference shielding structure can be used without a coverlay on a FPC, which reduces the cost.

The detailed characteristics and advantages are disclosed in the following description in order to facilitate understanding of the technical contents of the present invention for implementing the present invention for person skilled in the art. Accompany with disclosed contents, claims and diagrams in the application, it is apparent to any person skilled in the art to comprehend the objectives and advantages of the present invention.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1 illustrates the electromagnetic interference shielding structure of an embodiment according to the present invention; and

FIG. 2 illustrates a related art electromagnetic interference shielding structure

### DETAILED DESCRIPTION OF THE INVENTION

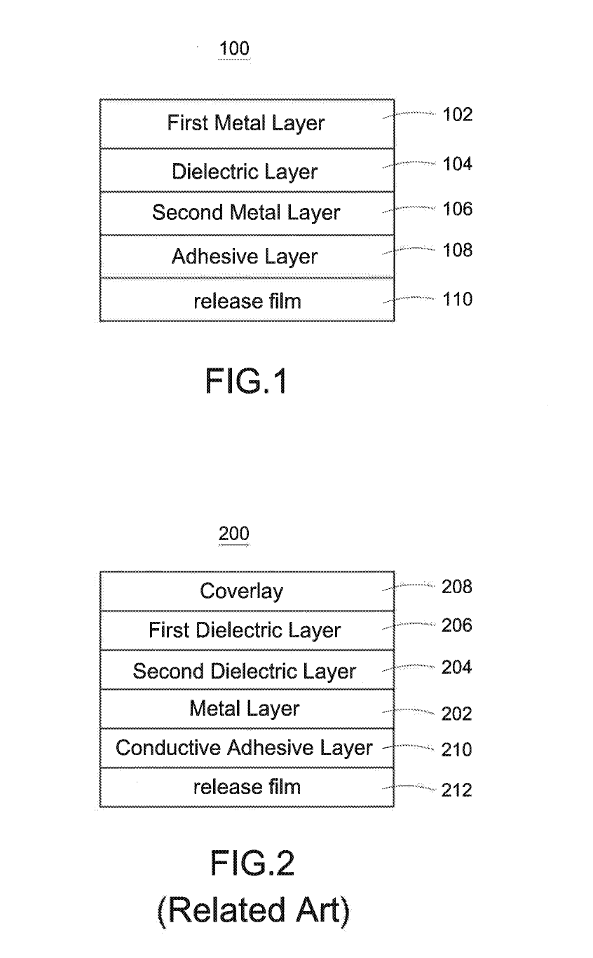

FIG. 1 illustrates the electromagnetic interference shielding structure of an embodiment according to the present invention. As shown in FIG. 1, the electromagnetic interference shielding structure 100 according to a top-down order comprises a first metal layer 102, a dielectric layer 104, a second metal layer 106, an adhesive layer 108 and a release film 110.

The components of the first metal layer 102 can be gold, silver, copper, iron, tin, lead, cobalt, aluminum, nickel or alloys using above metals as the principal components or any conductive metals, with thickness ranging from 0.002 micron (μm) to 12 micron. Because the first metal layer 102 is thin, electromagnetic waves penetrate into the electromagnetic interference shielding structure 100 through the gaps. In addition, a coverlay can be added to a first metal layer 102 (not shown in the diagram), the function of the coverlay is to protect a first metal layer 102 from interfering from external environment (such as oxidation, dusts, scratches, bumping . . . etc.).

The components of the dielectric layer 104 comprise dielectric layers formed by one or more than one of the polymer materials including polyimide (PI), polyethylene (PE), epoxy resin (EPOXY), polyethylene terephthalate (PET), polycarbonate (PC), polypropene (PP), bismaleimide (BMI) and acrylic polymers etc. In addition, filler materials can be added to the dielectric layer 104 facilitating diffraction of the electromagnetic waves with different phases in the dielectric layer 104 and accordingly the electromagnetic waves diminishes faster. The functions of the dielectric layer 104 are (1) providing insulation separating the first metal layer 102 from the second metal layer 106, (2) changing the incident angle of the electromagnetic waves such that the electromagnetic waves diffract among the dielectric layer 104, the first metal layer 102, and second metal layer 106 for diminishing the electromagnetic waves. The thickness of the dielectric layer 104 can be for example 5 micron to 200 micron.

The components of second metal layer 106 can be gold, silver, copper, iron, tin, lead, cobalt, aluminum, nickel or alloys using above metals as the principal components or any conductive metals. The thickness of the second metal layer 106 can be for example 0.002 micron (μm) to 12 micron. Because the second metal layer 106 is thin, electromagnetic waves penetrate into the electromagnetic interference shielding structure 100 through the gaps.

The components of the adhesive layer 108 comprise one or more than one polymers materials including PI, EPOXY, PE, PET, PC, PP, BMI and acrylic polymers etc. Filler materials can be added to the adhesive layer 108. The function of the adhesive layer 108 is providing insulation function for protecting circuits and binding the electromagnetic interference shielding materials with substrates. The thickness of the adhesive layer 108 can be 1 micron to 500 micron.

The components of the release film 110 comprise one or more than one polymers materials including PI, EPOXY, PE, PET, PC, PP, BMI and acrylic polymers etc. Filler materials can be added to the release film 110. The function of the release film 110 is to protect the adhesive layer from contaminating by external environment (such as hydrolysis, dusts . . . etc.). The release film 110 should be removed before using electromagnetic interference shielding structure 100. The thickness of the release film 110 can be 1 micron to 50 micron.

The achieved advantages by implementing the present invention are:

1. The thickness of an electromagnetic interference shielding structure (comprising a first metal layer 102, a dielectric layer 104, a second metal layer 106, an adhesive layer 108 and a release film 110) is controlled within 6 micron which meet the demand to miniaturize electronic products.

2. An electromagnetic interference shielding structure can be used as a electromagnetic shielding coverlay and reduce the product costs.

3. It is not required to add large size copper sheet for grounding in a substrate of an electromagnetic interference shielding structure, which reduces the cost for FPC manufacturers and meet the demand of offering lightweight products.

### EMBODIMENTS

### The First Embodiment

### The Ultra Slim Electromagnetic Interference Shielding Structure

The ultra slim electromagnetic interference shielding structure can be produced by the following manufacturing procedures, the steps are:

Provide a polyimide thin film which is 6 micron thick and coarsen the surface of the polyimide by the plasma or the corona method. Coat a silver layer (about 0.5 micron each) on any two dies of the polyimide thin film by sputtering (or vapor deposition), and coat epoxy resin of 3 micron thickness on one of the side. Then baking with high temperature (160° C.) to remove the solvent, laminate a release film onto the epoxy resin side to form a electromagnetic interference shielding structure unit of 10 micron thickness.

### The Second Embodiment

### The High Shielding Electromagnetic Interference Shielding Structure

The high shielding electromagnetic interference shielding structure can be produced by the following manufacturing procedures, the steps are:

Provide a glue-free polyimide substrate of 36 micron thickness having two sides covered by copper foil, and coat epoxy resin of 5 micron thickness on any of the sides. Then bake with high temperature (160° C.) to remove the solvent, and laminate a release film onto the epoxy resin side to form a electromagnetic interference shielding structure unit of 41 micron thickness.

### The Third Embodiment

### The Asymmetric Metal Electromagnetic Interference Shielding Structure

The asymmetric metal electromagnetic interference shielding structure can be produced by the following manufacturing procedures, the steps are:

Provide a glue-free polyimide substrate of 25 micron having one side covered by copper foil, and coarsen the surface of the polyimide by the plasma or the corona method. Coat a silver layer (about 0.5 micron each) on any two dies of the polyimide thin film by sputtering (or vapor deposition), and coat epoxy resin of 3 micron thickness on one the copper foil side or the silver foil side. Then bake with high temperature (160° C.) to remove the solvent, and laminate a release film onto the epoxy resin side to form a electromagnetic interference shielding structure unit of 30 micron thickness.

As the skilled person will appreciate, various changes and modifications can be made to the described embodiments. It is intended to include all such variations, modifications and equivalents which fall within the scope of the invention, as defined in the accompanying claims.

What is claimed is:

1. An electromagnetic interference shielding structure, comprising:
a dielectric layer, having a first side and a second side;
a first metal layer, located on the first side of the dielectric layer; and
a second metal layer, located on the second side of the dielectric layer,
wherein, the thickness of the first metal layer is 0.002 micron to 12 micron, and the thickness of the second metal layer is 0.002 micron to 12 micron.

2. The electromagnetic interference shielding structure of claim 1, wherein the first metal layer is gold, silver, copper, iron, tin, lead, cobalt, aluminum, nickel or alloys using above metals as the principal components.

3. The electromagnetic interference shielding structure of claim 1, wherein the second metal layer is gold, silver, copper, iron, tin, lead, cobalt, aluminum, nickel or alloys using above metals as the principal components.

4. The electromagnetic interference shielding structure of claim 1, wherein the dielectric layer is a material selected from the group consisting of polyimide (PI), polyethylene (PE), epoxy resin (EPOXY), Polyethylene terephthalate (PET), polycarbonate (PC), polypropene (PP), bismaleimide (BMI) and acrylic polymers.

5. The electromagnetic interference shielding structure of claim 1, wherein the thickness of the dielectric layer is 5 micron to 200 micron.

6. The electromagnetic interference shielding structure of claim 1, wherein the dielectric layer comprises a filler material.

7. The electromagnetic interference shielding structure of claim 1, further comprising an adhesive layer.

8. The electromagnetic interference shielding structure of claim 1, further comprising a release layer.

9. The electromagnetic interference shielding structure of claim 7, wherein the thickness of the adhesive layer is 1 micron to 500 micron.

10. The electromagnetic interference shielding structure of claim 8, wherein the thickness of the release layer is 1 micron to 50 micron.
